(19) United States
(12) Patent Application Publication
(10) Pub. No.: US 2026/0269601 A1
(43) Pub. Date: Sep. 10, 2026

(54) HYBRID SWITCHING DEVICE

(71) Applicant: ABB SCHWEIZ AG, Baden (CH)

(72) Inventors: Shuyan Zhao, Raleigh, NC (US); Jiale Zhou, Charlotte, NC (US); Govind Chavan, Garner, NC (US)

(21) Appl. No.: 19/069,804

(22) Filed: Mar. 4, 2025

(51) Int. Cl. H02H 9/02; H02H 9/00; H03K 17/0812; H03K 17/284

(52) U.S. Cl. CPC H02H 9/02; H02H 9/005; H03K 17/08122; H03K 17/08126; H03K 17/284

(57) ABSTRACT

A hybrid switch device for electrically coupling a power source to a load in a system may include a first switch at a first branch connected in parallel to a second switch at a second branch. The second switch may be coupled in parallel to a circuit protection device. The hybrid switch device may also include a third switch at the second branch and coupled in parallel to a circuit protection device. The circuit protection devices may prevent overvoltage during switching transients. The first switch may be a different type of switch than the second and third switches. A control circuit may be coupled to each of the switches and configured to selectively control, in response to an overload or fault event, the hybrid switch device to cause current to flow through the second branch from the first branch to extend a current-time conduction capability of the first switch.

### FIELD

The present disclosure relates to the field of switching devices. More particularly, to a hybrid solid-state switching device that provides enhanced overload capability and voltage utilization.

### BACKGROUND

Electrical power distribution systems typically include a switch device that electrically couples a power source to a load. The switch device can be located on a phase between the power source and the load. The power source can include, for example, a utility grid, generator, batteries, solar, etc., which can provide electrical current from the power source to the load devices. During normal operation, the switch device can be switched closed to supply electrical current from the power source to the load. In response to an electrical fault, the switch device can be switched open to isolate the load from the power source. Accordingly, the switch device is operable to provide electrical fault protection capabilities to protect the load or other devices connected upstream of the switch device in the system from the electrical fault, which can cause damage to the load or other devices connected to the system. The electrical fault can include, for example, an overload condition that causes a voltage surge in the electrical system.

### SUMMARY

In some embodiments, a device includes a first switch configured to couple a power source to a load on a first branch of a circuit and a second switch configured to couple the power source to the load via a second branch of the circuit that is in parallel with the first branch. In some embodiments, the first switch includes a different type of switch than the second switch. In some embodiments, the device includes a circuit protection device coupled to the second switch such that the circuit protection device is in parallel with the second switch within the second branch. In some embodiments, the device includes a control circuit coupled to the first and second switches and configured to selectively control, in response to detecting a surge current, the first and second switches to cause current to begin flowing through the second branch and stop flowing through the first branch.

In some embodiments, selectively controlling the first and second switches to cause current to begin flowing through the second branch and stop flowing through the first branch includes conducting the current on the first branch using the first switch according to a current-time limit profile of the first switch; driving, in response to exceeding the current-time limit profile of the first switch, the second switch closed and the first switch open such that the current flows from the first branch to the second branch; and driving, in response to exceeding a current-time limit profile of the second switch, the second switch open to cut-off the current at the second switch. In some embodiments, the circuit protection device is configured to commutate a voltage so as to clamp the voltage at the second branch below a threshold limit.

In some embodiments, the circuit protection device is a voltage clamping circuit including at least one of: a metal-oxide-varistor, or a transient-voltage-suppression diode.

In some embodiments, the circuit protection device includes a first circuit protection device. In some embodiments, the device further includes a third switch configured to couple the power source to the load via the second branch of the circuit that is in series with the second switch. In some embodiments, the third switch includes a different type of switch than the first switch. In some embodiments, the circuit protection device includes a second circuit protection device coupled to the third switch such that the second circuit protection device is in parallel with the third switch within the second branch. In some embodiments, the control circuit is further configured to selectively control the third switch to cause current to being flowing through the second branch and stop flowing through the first branch.

In some embodiments, the control circuit is further configured to drive, after the second switch is opened, the third switch open to cut-off the current at the third switch in response to exceeding a current-time limit profile of the third switch. In some embodiments, the second circuit protection device is configured to store a voltage commutated from the third switch to clamp the voltage at the second branch below a threshold limit and to decrease the voltage at the first circuit protection device.

In some embodiments, the second circuit protection device is a snubber circuit including at least one of a resistor, a capacitor, a diode, or a varistor.

In some embodiments, the second circuit protection device includes at least one of: a first snubber circuit including the resistor and the capacitor; a second snubber circuit including the resistor, the capacitor, and the diode; or a third snubber circuit including the resistor, the capacitor, and the varistor.

In some embodiments, the circuit is a two-quadrant switch.

In some embodiments, the first switch includes a SiC MOSFET. In some embodiments, each of the second switch and the third switch includes a Si IGBT including an IGBT co-packed with a Si Schottky diode.

In some embodiments, the circuit includes a first circuit. In some embodiments, the device further includes a second circuit configured to couple the power source to the load such that the second circuit is in anti-series connection with the first circuit. In some embodiments, the first circuit and the second circuit define a four-quadrant circuit.

In some embodiments, the system includes at least one circuit including a first switch configured to couple a power source to a load on a first branch of the at least one circuit, and a second switch configured to couple the power source to the load via a second branch of the at least one circuit that is in parallel with the first branch. In some embodiments, the second switch includes a different type of switch than the first switch. In some embodiments, the system includes a circuit protection device coupled to the second switch such that the circuit protection device is in parallel with the second switch within the second branch. In some embodiments, the system includes a control circuit coupled to the first and second switches and configured to selectively control, in response to detecting a surge current, the first and second switches to cause current to begin flowing through the second branch and stop flowing through the first branch.

In some embodiments, the circuit protection device includes a first circuit protection device. In some embodiments, the at least one circuit further includes a third switch configured to couple the power source to the load via the second branch of the at least one circuit that is in series with the second switch. In some embodiments, the third switch includes a different type of switch than the first switch. In some embodiments, the circuit protection device includes a second circuit protection device coupled to the third switch such that the second circuit protection device is in parallel with the third switch within the second branch. In some embodiments, the control circuit is further configured to selectively control the third switch to cause current to being flowing through the second branch and stop flowing through the first branch.

In some embodiments, the control circuit is configured to: conduct the current on the first branch using the first switch according to a current-time limit profile of the first switch; drive, in response to exceeding the current-time limit profile of the first switch, the second switch closed and the first switch open such that the current flows from the first branch to the second branch; drive, in response to exceeding a current-time limit profile of the second switch, the second switch open to cut-off the current at the second switch; and drive, after the second switch is opened, the third switch open to cut-off the current at the third switch in response to exceeding a current-time limit profile of the third switch. In some embodiments, the first circuit protection device is configured to commutate a voltage so as to clamp the voltage below a threshold limit during operation of the second switch. In some embodiments, the second circuit protection device is configured to store a voltage commutated from the third switch to clamp the voltage at the second branch below the threshold limit and to decrease the voltage at the first circuit protection device.

In some embodiments, the first circuit protection device includes a voltage clamping circuit including at least one of: a metal-oxide-varistor, or a transient-voltage-suppression diode.

In some embodiments, the second circuit protection device includes at least one of: a first snubber circuit including a resistor and a capacitor; a second snubber circuit including the resistor, the capacitor, and a diode; or a third snubber circuit including the resistor, the capacitor, and a varistor.

In some embodiments, the at least one circuit includes a first hybrid switching circuit, and a second hybrid switching circuit in anti-series connection with the first hybrid switching circuit. In some embodiments, the first and second hybrid switching circuits are in a bipolar configuration.

In some embodiments, the first switch includes a SiC MOSFET. In some embodiments, each of the second switch and the third switch includes a Si IGBT including an IGBT co-packed with a Si Schottky diode.

In some embodiments, a method includes detecting a surge current indicative of a fault condition at a circuit configured to couple a power source to a load; and selectively controlling, in response to detecting the surge current, a first switch on a first branch of the circuit and a second switch on a second branch of the circuit to cause current to begin flowing through the second branch and stop flowing through the first branch.

In some embodiments, selectively controlling the first switch on the first branch of the circuit and the second switch on the second branch of the circuit includes: conducting the current on the first branch using the first switch according to a current-time limit profile of the first switch; drive, in response to exceeding the current-time limit profile of the first switch, the second switch closed and the first switch open such that the current flows from the first branch to the second branch; and drive, in response to exceeding a current-time limit profile of the second switch, the second switch open. In some embodiments, a first circuit protection device is configured to commutate a voltage at the second switch so as to clamp the voltage at the second branch below a threshold limit.

In some embodiments, the second branch further includes a third switch and a second circuit protection device. In some embodiments, selectively controlling the first switch on the first branch of the circuit and the second switch on the second branch of the circuit further includes: drive, after the second switch is opened, the third switch open to cut-off the current at the third switch in response to exceeding a current-time limit profile of the third switch. In some embodiments, the second circuit protection device is configured to store a voltage commutated from the third switch to decrease the voltage at the first circuit protection device and to clamp the voltage at the second branch below the threshold limit.

### BRIEF DESCRIPTION OF THE DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a block diagram of an example system, according to some embodiments.

FIG. 2 is a schematic diagram of the hybrid switch device in FIG. 1, according to some embodiments.

FIG. 3 is a block diagram of an example system, according to some embodiments.

FIG. 4 is a schematic diagram of the example system, according to some embodiments.

FIG. 5 is a schematic diagram of the example system, according to some embodiments.

FIG. 6 is a schematic diagram of the example system, according to some embodiments.

FIG. 7 is a block diagram of an example system, according to some embodiments.

FIG. 8 is a schematic diagram of the example system, according to some embodiments.

FIG. 9 is a schematic diagram of the example system providing higher current-time conduction capabilities, according to some embodiments.

FIGS. 10a-10f are schematic diagrams of the example system providing the higher current-time conduction capabilities, according to some embodiments.

FIG. 11 is a flow diagram of an example method, according to some embodiments.

FIG. 12 is a flow diagram of an example method, according to some embodiments.

FIG. 13 is a flow diagram of an example method, according to some embodiments.

FIG. 14 is a graphical illustration of the switching operation of the hybrid switch device in system of FIG. 3 during an overload or a fault event, according to some embodiments.

### DETAILED DESCRIPTION

Electrical distribution systems can include an electrical switch device that may be operable to electrically couple or decouple a power source to a load at one or more phases to supply AC power from the power source to the load devices. The switch device can include one or more solid-state switch devices (SSSDs), which serve as electrical switches or relays that can be selectively turned on and off to switch between closed and opened positions, respectively, such that the switch device electrically couples or decouples the power source and the load and protects the load devices or other components connected to the system from electrical faults. Electrical faults can include, for example, overload conditions, electrical shorts, ground faults, arc faults, etc., which can cause damage to the load devices and/or to other electrical devices connected between the power source and the load. The SSSDs can thereby be selectively operable to electrically couple the power source to the load so as to supply the load with electrical current during a normal condition. In addition, the SSSDs can be selectively operable in accordance with the present disclosure to conduct the surging current in the forward and reverse directions for an extended time period compared to a time period of other types of known switch devices so as to provide enhanced overload or fault current capabilities and enhanced voltage utilization ratio.

Various embodiments of the present disclosure relate to systems and methods for a hybrid switch device configured to electrically couple a power source to a load to supply AC power to the load devices. The hybrid switch device can also be referred to herein as a switch device or a switch block. The hybrid switch device can include a first branch and a second branch connected in parallel to each other to provide parallel circuit conduction paths between the power source and the load at the hybrid switch device. The hybrid switch device can include one or more solid-state switch devices (SSSDs) that are selectively operable to conduct current between the power source and the load. The hybrid switch device is configured to selectively operate each of the one or more SSSDs to provide high efficiency nominal current conduction through the first branch and to extend the current-time conduction capability of the hybrid switch device by directing current to the second branch from the first branch during an overload or fault event when a current-time limit profile of the SSSD(s) at the first branch has been reached. In this regard, the hybrid switch device can utilize the one or more SSSDs to achieve high efficiency nominal current conduction and higher current-time limit conduction capabilities than with the SSSDs at the first branch alone during overload or fault events.

The hybrid switch device of the present disclosure improves upon other known switch devices by implementing a design that provides higher current-time limit conduction capabilities in both the forward and reverse directions in response to an overload or fault event and also provides high efficiency nominal current conduction capabilities. The hybrid switch device includes a first SSSD at the first branch to achieve the high efficiency nominal current conduction through the first branch. The hybrid switch device includes at least one other SSSD at the second branch. In some embodiments, the hybrid switch device can include a second SSSD having a circuit protection device at the second branch to achieve the higher-current-time limit conduction capabilities. In some embodiments, the hybrid switch device can include a third SSSD having a circuit protection device in series connection with the second SSSD at the second branch to achieve the higher-current-time limit conduction capabilities. By selectively operating the SSSDs between the open and closed positions to direct the current from the first branch to the second branch during electrical faults once the current-time limit profile of the first SSSD at the first branch has been reached, the hybrid switch device can enhance the total current-time conduction capability of the hybrid switch device.

Accordingly, the hybrid switch device of the present disclosure improves upon other switch devices that primarily utilize metal-oxide-semiconductor field-effect transistor (MOSFET) in their topology by providing a switch device topology that utilizes a first type of SSSD at the first branch that exhibits high efficiency nominal current conduction and utilizes a second type of SSSD at the parallel second branch that exhibits higher current-time conduction capabilities for overload or fault current as compared to using primarily, for example, MOSFETs. The hybrid switch device of the present disclosure improves upon other switch devices that primarily utilize MOSFETs as the main switches to achieve the required voltage blocking capabilities because MOSFETs typically exhibit higher conduction losses at overload or fault events and exhibit limited current-time conduction capabilities compared to other types of solid-state switches. In addition, pure MOSFET-based switching blocks are also costly to manufacture when designed to have multiple switches connected in parallel.

The hybrid switch device of the present disclosure also improves upon other switch devices that include, for example, a MOSFET and an IGBT connected in parallel by implementing a topology that provides enhanced current conduction capability and that ensure smooth current transfer from one branch to the other using relatively simpler gate driver and control circuit designs compared to other switch devices. These other switch devices typically require more complex gate driver and control circuit designs to selectively operate the MOSFET and IGBT to provide smooth current transfer from one switch device to the other during the overload or fault event so as not to exceed the operational parameters of the MOSFET and IGBT. These gate driver and control designs of these other switch devices typically require relatively more complex designs and has more demanding gate driver control requirements to ensure smooth current transfer from one switch device to the other because of the different parasitic capacitances of MOSFETs and IGBTs which affects their respective turn-on and turn-off speeds.

The hybrid switch device of the present disclosure also improves upon other switch devices by implementing a topology that provides voltage clamping and energy dissipation capability but yet reduces a main switch overdesign ratio while being able to provide enhanced current-time conduction capability. In addition, the hybrid switch device also reduces leakage current when in the off state. Other switch devices typically include a metal-oxide-varistor (MOV) to dissipate inductive energy and protect the MOSFET at the opening event. However, in these other devices, connecting the MOV in parallel with the MOSFET requires substantial overdesign in order for the other switch devices to provide the requisite voltage blocking capabilities, which is around 2-2.5× of system nominal voltage due to the higher conduction losses of MOSFETs. The hybrid switch device topology of the present disclosure reduces the main switch overdesign ratio and reduces the switch blocking voltage to 1.2-1.4× of the system nominal voltage.

The hybrid switch device topology having a lower switch blocking voltage allows for providing a more efficient switch block (e.g., power block) with a smaller form factor compared to other switch devices, as it allows for the use of smaller semiconductor die sizes and reduces the power dissipation within the hybrid switch device, which leads to improved overall system efficiency and can lower the cost of manufacturing the hybrid switch device depending on the intended application of the hybrid switch device.

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

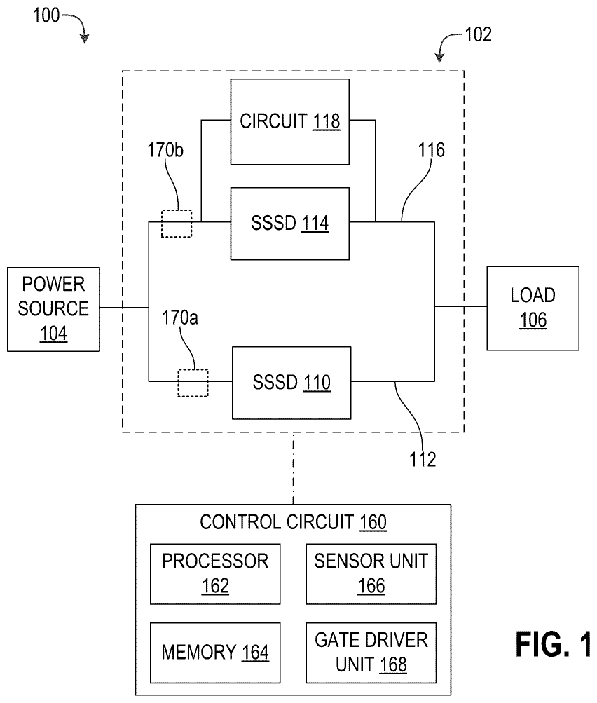

FIG. 1 is a block diagram of an example system 100, according to some embodiments.

The system 100 can be an electrical system including a hybrid switch device 102 for electrically coupling a power source 104 to a load 106 to supply electrical current and power the load 106 devices. The hybrid switch device 102 can also electrically decouple the power source 104 from the load 106 such as, for example, during an electrical fault event that causes an overload or short-circuit current so as to protect the load 106 devices from potential damage. The hybrid switch device 102 can be referred to herein as a switch device, switch block, or hybrid switch block.

The hybrid switch device 102 can have a topology suitable to electrically couple the power source 104 to the load 106 in the system 100. In some embodiments, the hybrid switch device 102 can have a topology capable of electrically coupling the power source 104 to the load 106 across one or more phases of system 100. For example, the system 100 can include a switch block including a hybrid switch device 102 located between the power source 104 and the load 106 at each phase. In some embodiments, the system 100 can include one or more hybrid switch device 102 located between the power source 104 and the load 106 at each respective phase of system 100. For example, the system 100 can include two of the hybrid switch device 102 located at each of a first, second, and third phases to electrically couple the power source 104 to the load 106.

The hybrid switch device 102 includes one or more solid state switching devices (SSSDs) selectively operable to switch between an open position (i.e., turn off state) and a closed position (i.e., turn on state) using gate driver signals to electrically couple or decouple the power source 104 and the load 106. The hybrid switch device 102 can be referred to herein as switch device 102 and the SSSDs can be referred to herein as switches. The hybrid switch device 102 includes a SSSD 110, a SSSD 114, and a circuit protection device 118. The SSSD 110 is located on a branch 112. The SSSD 110 is located on a branch 116, and the branch 116 is connected in parallel to branch 112 at the hybrid switch device 102. The circuit protection device 118 is connected in parallel to SSSD 114, and thereby is connected in parallel to branch 116.

The hybrid switch device 102 utilizes the SSSD 110, SSSD 114, and circuit protection device 118 to direct current through branch 112 to provide high efficiency nominal current conduction capabilities and to direct current through branch 116 to provide higher current-time limit conduction capabilities for overload or fault current. The hybrid switch device 102 can turn on SSSD 110 to switch to the closed position to conduct a nominal system current through branch 112 to provide the high efficiency nominal current conduction capabilities. In response to detecting an electrical fault in system 100, the hybrid switch device 102 can maintain the SSSD 110 in the closed position to conduct the overload or fault current through the branch 112 for a certain time period according to a current-time limit profile of the SSSD 110. In response to approaching a limit of the current-time limit profile of the SSSD 110, the hybrid switch device 102 can turn on SSSD 114 to switch to the closed position and can turn off SSSD 110 to switch to the open position to conduct the overload or fault current through branch 116 from branch 112 for a certain time period according to a current-time limit profile of the SSSD 114.

According to some embodiments, the system 100 can include a control circuit 160 in electrical connection with the hybrid switch device 102 to selectively operate the SSSDs of the hybrid switch device 102 according to, for example, measurements indicative of an operational parameter of the system 100 or the hybrid switch device 102 by one or more sensors 170. The control circuit 160 can include one or more components including a processor 162, a memory 164, a sensor unit 166, and a gate driver unit 168. The control circuit 160 can include a bus (not shown), and the one or more components of the control circuit 160 can be in electronic communication with each other via the bus.

The processor 162 is configured to execute instructions stored in the memory 164 such as, for example, instructions for selectively operating each of the SSSDs in the hybrid switch device 102 according to a current-time limit profile of each SSSD. The memory 164 is a non-transitory computer-readable medium having stored thereon instructions that are executable by the processor 162 to perform operations including electrically coupling the power source 104 to the load 106 using the SSSDs (e.g., SSSD 110, 114) in the hybrid switch device 102 to provide high efficiency nominal current conduction capabilities and selectively operating the SSSDs (e.g., SSSD 110, 114) in the hybrid switch device 102 to provide higher current-time limit conduction capabilities during electrical fault conditions.

The control circuit 160 can be in electrical connection with the one or more sensors 170 using a wired connection or using a wireless connection according to any of a plurality of wireless communication protocols such that the control circuit 160 can receive the sensor measurements from the one or more sensors 170. Each of the sensors 170 can measure any of a plurality of operational parameters of the system 100 including, but not limited to, voltage, current, resistance, inductance, frequency, temperature, vibration, other parameters, or any combination thereof. As shown in FIG. 1, for example, the system 100 can include a sensor 170a for measuring voltage at the branch 112 and a sensor 170b for measuring voltage at the branch 116. It is to be appreciated that the system 100 is not intended to be limited to including sensor 170a and sensor 170b, and that the system 100 can include more sensors or less sensors located in the system 100 or the hybrid switch device 102 for measuring an operational parameter. It is also to be appreciated that the one or more sensors 170 is not intended to be limited to measuring only voltage, and the one or more sensors 170 can measure one or more other parameters including voltage at the system 100 or hybrid switch device 102.

The sensor unit 166 can be in electrical connection with the one or more sensors 170 in the system 100, hybrid switch device 102, or both, such that the control circuit 160 can receive measurement signals corresponding to the detected operational parameters from the one or more sensors 170. The processor 162 can utilize the received measurement signals to control an operation of the hybrid switch device 102. For example, the control circuit 160 can selectively operate the one or more SSSDs in the hybrid switch device 102 to direct a nominal current through branch 112. For example, the control circuit 160 can selectively operate the one or more SSSDs in the hybrid switch device 102 to direct the overload or fault current to branch 116 from branch 112 based on the current-time limit profile of SSSD 110.

The gate driver unit 168 can be electrically connected to each of the SSSDs of the hybrid switch device 102 and the gate driver unit 168 can selectively send gate driver signals to each of the SSSDs. In some embodiments, the gate driver unit 168 can output a first gate driver signal to turn off the SSSD 110 to interrupt current at the branch 112. In some embodiments, the gate driver unit 168 can output a second gate driver signal to turn on the SSSD 110 to conduct current at the branch 112. In some embodiments, the gate driver unit 168 can output a first gate driver signal to turn off the SSSD 114 to interrupt current at branch 116 at SSSD 114. In some embodiments, the gate driver unit 168 can output a second gate driver signal to turn on the SSSD 114 to conduct current at branch 116 at SSSD 114.

According to some embodiments, the control circuit 160 can include one or more other components for controlling the hybrid switch device 102 or other devices of system 100. For example, the system 100 can include a hybrid switch device 102 located at each phase between the power source 104 and the load 106 and the control circuit 160 can be electrically connected to the hybrid switch device 102 located at each phase to selectively operate each hybrid switch device 102 and to selectively operate the SSSDs located in each hybrid switch device 102.

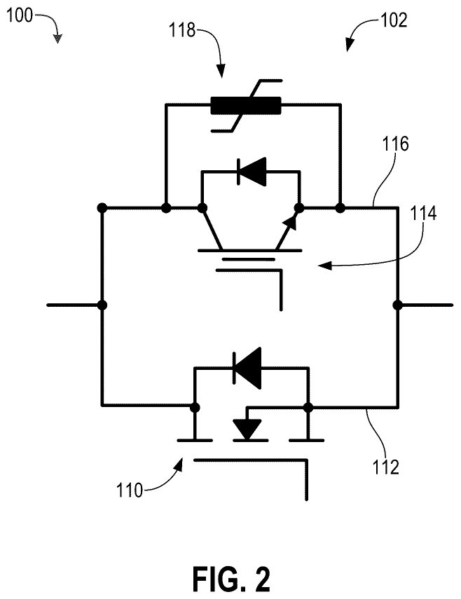

FIG. 2 is a schematic diagram of the hybrid switch device 102 in FIG. 1, according to some embodiments.

The hybrid switch device 102 includes SSSD 110, SSSD 114, and circuit protection device 118. The SSSD 110 is located at branch 112. The SSSD 114 is located at branch 116, which is connected in parallel to branch 112. The circuit protection device 118 is connected in parallel to the SSSD 114 and the branch 116. In some embodiments, the circuit protection device 118 can be described as being located on a third branch 120 connected in parallel to the branch 116 and in parallel to SSSD 114.

The hybrid switch device 102 can include different SSSD types having different operational characteristics. The hybrid switch device 102 can include different SSSD types because they exhibit different performance advantages over each other. The hybrid switch device 102 can include a first type of SSSD and a second type of SSSD.

The hybrid switch device 102 can include the first type of SSSD at the branch 112. The first type of SSSD can provide the hybrid switch device 102 with high efficiency nominal conduction capabilities. The first type of SSSD can conduct an overload or short-circuit current for a limited time according to a current-time limit profile of the first type of SSSD. In some embodiments, the first type of SSSD can include a MOSFET. In some embodiments, the first type of SSSD can include a SiC MOSFET.

The hybrid switch device 102 can include the second type of SSSD at the branch 116. The second type of SSSD can provide the hybrid switch device 102 with higher current-time conduction capabilities for overload or surging fault currents. The second type of SSSD can be utilized in the hybrid switch device 102 to conduct the overload or fault current after the first type of SSSD to achieve higher current-time capabilities in the forward and reverse directions. In some embodiments, the second type of SSSD can include an IGBT. In some embodiments, the second type of SSSD can include an Si IGBT. The Si IGBT includes an IGBT co-packed with a Schottky diode. The second type of SSSD can include the IGBT to conduct the forward current to achieve higher forward current-time capabilities. The second type of SSSD can include the Schottky diode to conduct the reverse current to achieve higher reverse current-time capabilities.

The hybrid switch device 102 can include the circuit protection device 118 connected in parallel to SSSD 114. The circuit protection device 118 can commutate the voltage at branch 116 to the circuit protection device 118 during turn-off events of SSSD 114 to provide the hybrid switch device 102 with voltage clamping and energy dissipation capabilities. In some embodiments, the circuit protection device 118 can include a metal oxide varistor (MOV) connected in parallel to SSSD 114. It is to be appreciated that the circuit protection device 118 is not limited to including a MOV and can include any of a plurality of electrical components capable of providing the hybrid switch device 102 with the voltage limiting and energy dissipation capabilities described with regards to the present disclosure.

Referring to FIG. 2, the hybrid switch device 102 includes SSSD 110 located at branch 112, SSSD 114 located at branch 116, and circuit protection device 118 connected in parallel to SSSD 114. The SSSD 110 is a first type of SSSD. In some embodiments, the first type of SSSD includes a SiC MOSFET. The first type of SSSD provides the hybrid switch device 102 with high efficiency nominal conduction capabilities. That is, the first type of SSSD can be utilized for its fast switching capabilities. However, the first type of SSSD can exhibit higher conduction losses such that the first type of SSSD can only conduct the short-circuit current for a limited time when an overload or fault event occurs before having to be turned off to avoid potentially causing damage. The SSSD 114 is a second type of SSSD. In some embodiments, the second type of SSSD includes an IGBT. In some embodiments, the second type of SSD includes an IGBT co-packed with a Schottky diode. The second type of SSSD provides the hybrid switch device 102 with higher current-time conduction capabilities in the forward and reverse directions for overload or surging fault currents.

Hybrid switch device 102 can include SSSD 110 for its fast switching capabilities to interrupt current in response to detecting a fault event. However, the SSSD 110 typically has a higher cost than the SSSD 114. Accordingly, although the SSSD 114 may demonstrate lower efficiency than the SSSD 110, the hybrid switch device 102 can include SSSD 114 for its higher current-time conduction capabilities in the forward and reverse directions and to reduce the costs associated with manufacturing the hybrid switch device 102. In addition, SSSD 110 can require a more robust cooling system to dissipate losses than compared to SSSD 114, which can further increase the cost of the hybrid switch device 102 and can increase the physical dimensions of the hybrid switch device 102. Accordingly, the hybrid switch device 102 can utilize the SSSD 114 on the branch 116 to further decrease the cost associated with manufacturing the hybrid switch device 102 and to decrease the overall physical dimensions of the hybrid switch device 102 because of the cooling system requirements associated with the SSSD 110.

The hybrid switch device 102 conducts the nominal current through branch 112 by turning on SSSD 110 to the closed position. When an overload of fault event occurs in system 100, the hybrid switch device 102 can maintain the SSSD 110 turned on and in the closed position to conduct the current through branch 112 using SSSD 110 for a certain time period according to the current-time limit profile of the SSSD 110. When the overload or fault current approaches the current-time limit profile of the first switch, the hybrid switch device 102 can turn on SSSD 114 to the closed position and turn off SSSD 110 to the open position, such that the current is conducted through branch 116 from branch 112 using SSSD 114. The hybrid switch device 102 can maintain the SSSD 114 turned on and in the closed position to conduct the current through branch 116 using SSSD 114 for a certain time period according to the current-time limit profile of the SSSD 114.

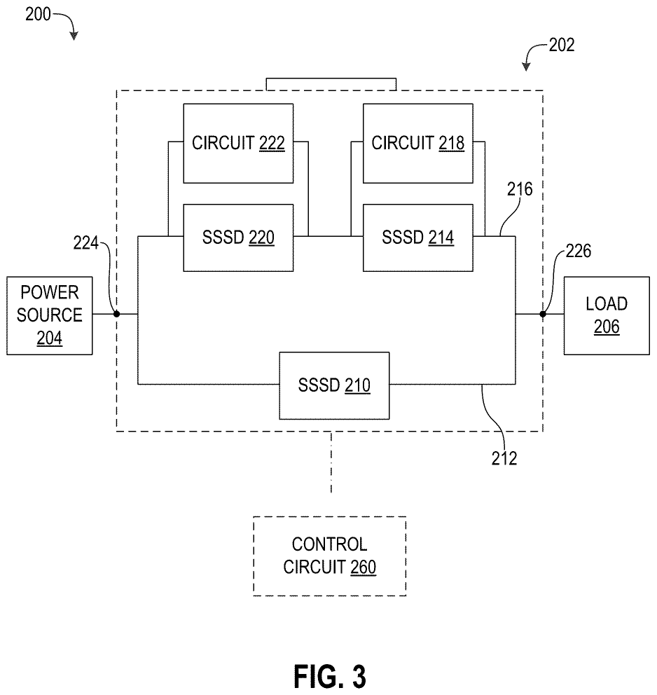

The circuit protection device 118 is connected in parallel to the SSSD 114 and branch 116. The hybrid switch device 102 utilizes the circuit protection device 118 to commutate the voltage to the circuit protection device 118 during a switching transient of SSSD 114 so as to clamp the voltage to less than a threshold limit and to dissipate an inductive energy at the hybrid switch device 102. In some embodiments, the circuit protection device 118 can include a voltage clamping circuit. Referring to FIG. 2, the circuit protection device 118 includes a MOV connected in parallel to SSSD 114. In some embodiments, the circuit protection device 118 can include a snubber circuit in place of the voltage clamping circuit, as further described herein with regards to circuit protection device 222 in FIG. 3 below.

FIG. 3 is a block diagram of an example system 200, according to some embodiments. The system 200 can be an embodiments of system 100 of FIG. 1.

The system 200 can be an electrical system including a hybrid switch device 202 for electrically coupling a power source 204 to a load 206 to supply electrical current and power the load 206 devices. The hybrid switch device 202 can also electrically decouple the power source 204 from the load 206 such as, for example, during an electrical fault event that causes an overload or fault current so as to protect the load 206 devices from potential damage. The hybrid switch device 202 can be referred to herein as a switch device, switch block, or hybrid switch block. The hybrid switch device 202 can be an embodiment of hybrid switch device 102, according to some embodiments.

The hybrid switch device 202 includes one or more SSSDs selectively operable to switch between an open position (i.e., turn off state) and a closed position (i.e., turn on state) to electrically couple or decouple the power source 204 and the load 206. For example, the SSSDs can be selectively operated using gate driver signals from a gate driver.

The hybrid switch device 202 includes SSSD 210 located on branch 212, SSSD 214 located on branch 216, circuit protection device 218, SSSD 220 located on branch 216, and circuit protection device 222. The branch 216 is connected in parallel to branch 212. In addition, the SSSD 220 is connected in series to SSSD 214 on branch 216. Accordingly, the SSSD 210 located on branch 212 is connected in parallel to the SSSD 214 and the SSSD 220 located on branch 216. The circuit protection device 218 is connected in parallel to SSSD 214, and the circuit protection device 222 is connected in parallel to SSSD 220.

The hybrid switch device 202 includes an input terminal 224 and an output terminal 226. The power source 204 can be electrically coupled to the input terminal 224 of the hybrid switch device 202. The load 206 can be electrically coupled to the output terminal 226 of the hybrid switch device 202. In hybrid switch device 202, the SSSD 214 can be arranged on branch 216 between the SSSD 220 and the output terminal 226, and the SSSD 220 can be arranged on branch 216 between the SSSD 214 and the input terminal 224. In some embodiments, the SSSD 214 can be an embodiment of SSSD 114 of FIG. 1. In some embodiments, the SSSD 220 can be an embodiment of SSSD 114 of FIG. 1. In some embodiments, the SSSD 210 can be an embodiment of SSSD 110 of FIG. 1.

The hybrid switch device 202 utilizes SSSD 210 to direct current through branch 212 to provide high efficiency nominal current conduction capabilities. The hybrid switch device 202 utilizes SSSD 214 and SSSD 220 to direct current through branch 216 to provide higher current-time limit conduction capabilities for the overload or short-circuit current. The hybrid switch device 202 can selectively operate the SSSD 210, SSSD 214, and SSSD 220 to conduct current through branch 212 or branch 216, to interrupt current (i.e., cut off current) through branch 212 or branch 216, to interrupt current at both branch 212 and branch 216, and to redirect current from one of branch 212 and branch 216 to the other of branch 212 and branch 216.

The hybrid switch device 202 can turn on SSSD 210 to the closed position to conduct a nominal system current through branch 212 to provide the high efficiency nominal current conduction capabilities. In response to detecting an electrical fault in system 200, the hybrid switch device 202 can maintain the SSSD 210 in the closed position to conduct the overload or fault current through the branch 212 for a certain time period according to a current-time limit profile of the SSSD 210. In response to approaching a limit of the current-time limit profile of the SSSD 210, the hybrid switch device 202 can turn on SSSD 214 and SSSD 220 to the closed positions and can turn off SSSD 210 to the open position to conduct the overload or fault current through branch 216 from branch 212 for a certain time period according to a current-time limit profile of SSSD 214 and SSSD 220. After the turn off of SSSD 210 and during a current-time limit profile of SSSD 214, the hybrid switch device 202 can turn off SSSD 214 to the open position to cut-off the current at the SSSD 214, and the circuit protection device 218 can commutate the voltage to the circuit protection device 218 to dissipate the inductive energy and to clamp the voltage to less than a threshold limit. Once SSSD 214 is turned off, and in response to approaching a limit of the current-time limit profile of the SSSD 220, the hybrid switch device 102 can turn off SSSD 220 to the open position to cut-off the current at the SSSD 220 and at branch 216. The circuit protection device 222 can commutate the voltage from the circuit protection device 218, thereby increasing the nominal voltage withstanding capability of the hybrid switch device 202 and reducing the leakage current of the hybrid switch device 102 in the off state.

According to some embodiments, the system 200 can include a control circuit 260. The control circuit 260 can be an embodiment of the control circuit 160 in FIG. 1. The control circuit 260 can be in electrically connected to the SSSDs in the hybrid switch device 202 to perform the operations described above. For example, the control circuit 260 can include a gate driver such as gate driver unit 168 in FIG. 1 to selectively send gate driver signals to at least one of SSSD 210, SSSD 214, or SSSD 220.

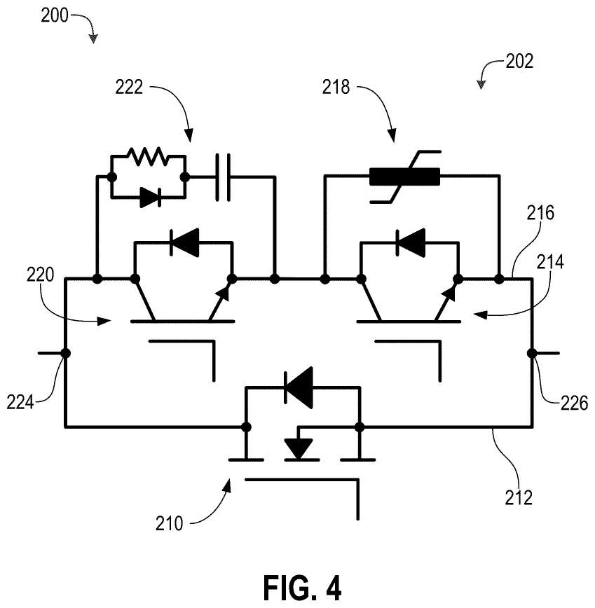

FIG. 4 is a schematic diagram of the example system 200, according to some embodiments.

The hybrid switch device 202 can be a switch block having a unipolar configuration. The hybrid switch device 202 can be a two-quadrant switch capable of conducting current in both directions but can only block voltage in one polarity. The hybrid switch device 202 includes SSSD 210, SSSD 214, circuit protection device 218, SSSD 220, and circuit protection device 222. The SSSD 210 is connected to branch 212 to provide the hybrid switch device 202 with high efficiency nominal current conduction capabilities. The SSSD 214 and SSSD 220 are connected in series to branch 216 to provide the hybrid switch device 202 with higher current-time conduction capabilities during fault events that cause overcurrent or fault current that exceeds the current-time limit profile of SSSD 210. The branch 212 is connected in parallel to branch 216, such that the SSSD 210 is connected in parallel to SSSD 214 and SSSD 220. Accordingly, turning on SSSD 214 and SSSD 220 and turning off SSSD 210 causes the current to conduct through branch 216 from branch 212.

The circuit protection device 218 is connected in parallel to SSSD 214 to commutate voltage to the circuit protection device 218 during a turn off event of SSSD 214 so as to clamp voltage to less than a threshold limit and dissipate energy.

The circuit protection device 222 is connected in parallel to SSSD 220 to commutate voltage to the circuit protection device 222 during a turn off event of SSSD 220 and to store voltage from circuit protection device 218 to increase the nominal voltage withstanding capability of the hybrid switch device 202 and reduce the leakage current of the hybrid switch device 102 in the off state.

The hybrid switch device 202 also includes input terminal 224 and output terminal 226 for connecting the hybrid switch device 202 to the power source 204 and the load 206, respectively. The hybrid switch device 202 can thereby electrically couple or decouple the load 206 from the power source 204 to provide system 200 with fault isolation capabilities.

According to some embodiments, in hybrid switch device 202, the SSSD 210 located on branch 212 can be a first type of SSSD, and the SSSD 214 and SSSD 220 located on branch 216 can be a second type of SSSD. Referring to FIG. 4, in the hybrid switch device 202, the SSSD 210 located on branch 212 is the first type of SSSD and includes a SiC MOSFET to achieve the high efficiency nominal current conduction, and the SSSD 214 and SSSD 220 located on branch 216 is the second type of SSSD and can be an Si IGBT including an IGBT and a Schottky diode to achieve the higher current-time conduction.

The hybrid switch device 202 can include the circuit protection device 218 connected in parallel to SSSD 214. The circuit protection device 218 can commutate the voltage at branch 216 to the circuit protection device 218 during turn-off events of SSSD 214 to achieve the voltage clamping and energy dissipation capabilities at the hybrid switch device 202. In some embodiments, the circuit protection device 218 can include a metal oxide varistor (MOV) connected in parallel to SSSD 214. It is to be appreciated that the circuit protection device 218 is not limited to including a MOV and can include any of a plurality of electrical components capable of providing the hybrid switch device 202 with the voltage limiting and energy dissipation capabilities described with regards to the present disclosure.

The hybrid switch device 202 can include the circuit protection device 222 connected in parallel to SSSD 220. The circuit protection device 222 can commutate the voltage at branch 216 to the circuit protection device 222 to prevent overvoltage during turn-off events of SSSD 220 and to increase the nominal voltage withstanding capability of the hybrid switch device 202 and reduce the leakage current of the hybrid switch device 102 in the turn off state. In some embodiments, the circuit protection device 222 can include a snubber circuit connected in parallel to SSSD 220. The circuit protection device 222 can include a snubber circuit including one or more electrical components suitable for preventing overvoltage at the SSSD 220 during switching transients. Referring to FIG. 4, the circuit protection device 222 includes a RCD snubber circuit, and the RCD snubber circuit includes a resistor connected in parallel to a diode, and the resistor and diode are connected is series to a capacitor. It is to be appreciated that the circuit protection device 222 is not limited to including a RCD snubber circuit and can include any of a plurality of configurations capable of providing the hybrid switch device 202 with the voltage limiting and energy dissipation capabilities described with regards to the present disclosure.

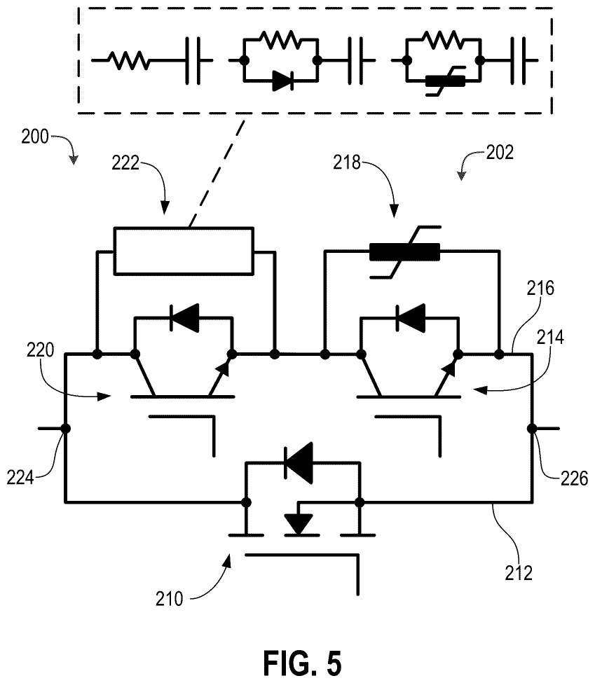

FIG. 5 is a schematic diagram of the example system 200, according to some embodiments.

In hybrid switch device 202, the SSSD 220 is located at branch 216 and the circuit protection device 222 is connected in parallel to SSSD 220. The circuit protection device 222 clamps the voltage below a threshold limit and provides energy dissipation capabilities to the hybrid switch device 202 by commutating the voltage at branch 216 at SSSD 220 to the circuit protection device 218 during turn-off events of SSSD 220 to prevent overvoltage at SSSD 220.

The circuit protection device 222 can include a snubber circuit. The circuit protection device 222 can charge the one or more electrical components therein from the commutated current to prevent overvoltage at SSSD 220 during the turn off or turn on event. In some embodiments, the circuit protection device 222 can be charged from the current at branch 216. In some embodiments, the circuit protection device 222 can be charged from the current from circuit protection device 218 so as to decrease the voltage across SSSD 214.

Referring to FIG. 5, the circuit protection device 222 can include a snubber circuit. The circuit protection device 222 can include any of a plurality of snubber circuits that is compatible with the hybrid switch device 202 for protecting the SSSD 220 from overvoltage during switching transients. In some embodiments, the circuit protection device 222 can include a RCD snubber circuit, a RC snubber circuit, or a RCV snubber circuit, among other types of snubber circuits.

In some embodiments, the circuit protection device 222 can include a RC snubber circuit. The circuit protection device 222 utilizes the resistor (R) to limit current through the capacitor (C) and to dissipate some of the energy stored in the parasitic elements. The capacitor (C) absorbs the voltage spikes and reduces a rate of change of voltage (dv/dt) across SSSD 220 during switching transients.

In some embodiments, the circuit protection device 222 can include a RCD snubber circuit. The circuit protection device 222 can include a diode (D) connected in parallel to the resistor (R), and the resistor (R) and diode (D) can be connected in series with the capacitor (C). The diode (D) can bypass the resistor during the turn-on of the switch, allowing the capacitor (C) to charge quickly and reduce turn-on losses. The diode can also be utilized to block the reverse current during the turn-off of SSSD 220, forcing current to flow through the resistor (R) and causing the discharge of the capacitor (C), the resistor (R) then absorbs the energy stored in the parasitic elements and limits turn-off losses.

In some embodiments, the circuit protection device 222 can include a RCV snubber circuit. The diode of the RCD snubber circuit can be functionally replaced with a MOV such that there is no continuous voltage stress across the MOV as compared to a diode. In the hybrid switch device 202, the circuit protection device 222 can include a RCV snubber circuit due to its lower overall cost compared to RCV snubber circuits. The MOV can bypass the resistor (R) to allow the capacitor (C) to charge and reduce turn-on losses. The MOV can also be utilized to block the reverse current during the turn-off of SSSD 220, forcing current to flow through the resistor (R) and causing the discharge of the capacitor (C), the resistor (R) then absorbs the energy stored in the parasitic elements and limits turn-off losses.

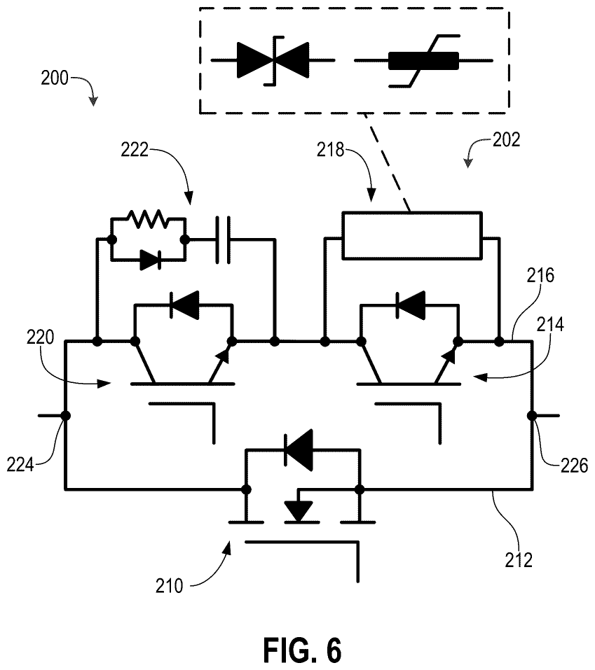

FIG. 6 is a schematic diagram of the example system 200, according to some embodiments.

In hybrid switch device 202, the SSSD 214 is located at branch 216 and the circuit protection device 218 is connected in parallel to SSSD 214. The circuit protection device 218 clamps the voltage below a threshold limit and provides energy dissipation capabilities to the hybrid switch device 202 by commutating the voltage at branch 216 at SSSD 214 to the circuit protection device 218 during turn-off events of SSSD 214 to prevent overvoltage at SSSD 214. The circuit protection device 218 can include a voltage clamping circuit. The circuit protection device 218 can prevent overvoltage at SSSD 214 by commutating the voltage to the circuit protection device 218 during switching transients of SSSD 214.

Referring to FIG. 6, the circuit protection device 218 can include a voltage clamping circuit. The circuit protection device 218 can include any of a plurality of voltage clamping circuits that is compatible with the hybrid switch device 202 for protecting the SSSD 214 from overvoltage during switching transients. In some embodiments, the circuit protection device 218 can include a MOV. In some embodiments, the circuit protection device 218 can include a transient-voltage-suppression (TVS) diode. It is to be appreciated that the circuit protection device 218 is not intended to be limited to including the MOV or the TVS diode, and the circuit protection device 218 can include any of a plurality of electrical components including the MOV and the TVS diode that may be suitable for providing the overvoltage protection to SSSD 214 during switching transients in the hybrid switch device 202.

In some embodiments, the circuit protection device 218 can include a MOV. The MOV can have current-voltage characteristics such that the MOV resistance can change based on the applied voltage. When the voltage exceeds a certain threshold, the resistance at the MOV can be reduced to divert excess current away from SSSD 214 to prevent overvoltage at SSSD 214.

In some embodiments, the SSSD 214 can include a TVS diode. The TVS diode can clamp the voltage at a certain threshold limit. The TVS diode can absorb the excess voltage as heat. The TVS diode can be turned on by, for example, a control circuit using control signals such as, for example, control circuit 260.

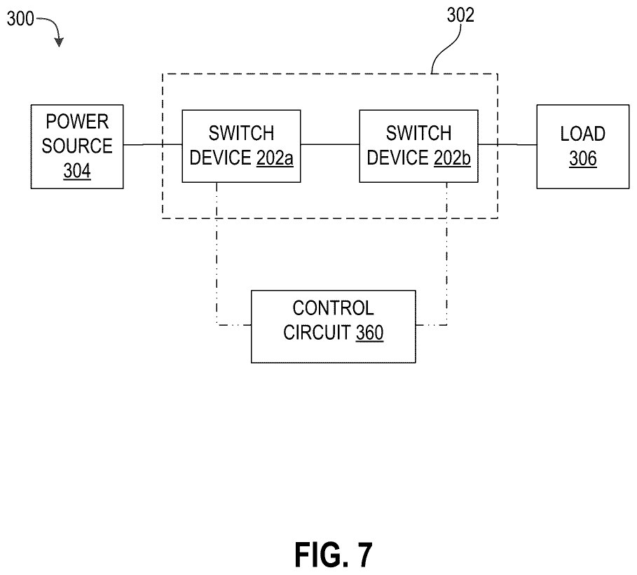

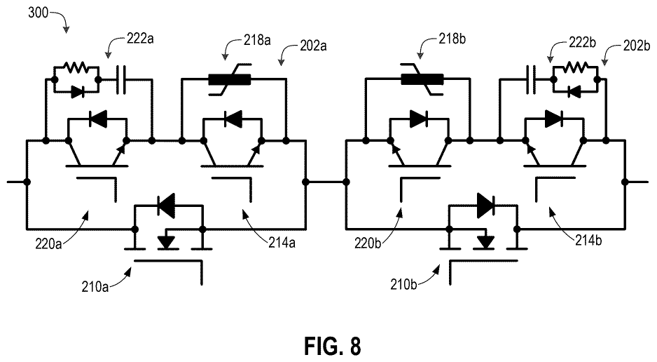

FIG. 7 is a block diagram of an example system 300, according to some embodiments. FIG. 8 is a schematic diagram of the example system 300, according to some embodiments. Unless specifically referenced, FIGS. 7 and 8 will be described collectively. The system 300 can be an embodiment of system 100 of FIG. 1, or of system 200 of FIG. 3.

The system 300 includes a switch block 302, a power source 304, a load 306. The switch block 302 can include one or more hybrid switch devices. Referring to FIG. 7, the switch block 302 includes switch device 202a and switch device 202b connected in series between power source 304 and load 306. The switch devices 202a, 202b can be an embodiment of hybrid switch devices 102, 202.

The switch block 302 can be selectively operable to electrically couple or decouple the load 306 from the power source 304. For example, the switch block 302 can conduct nominal current with high efficiency to supply power from the power source 304 to the load 306. The switch block 302 can also be selectively operable to achieve higher current-time conduction capabilities. For example, during an overload or fault event, the switch block 302 can provide enhanced current-time capability and switch voltage utilization ratio. In system 300, the switch block 302 can be connected in anti-series to each other between the power source 304 and the load 306. Referring to FIG. 8, the switch block 302 is shown having a bipolar configuration and includes hybrid switch device 202a connected in anti-series to hybrid switch device 202b.

In some embodiments, the power source 304 can include one or more power sources. For example, the power source 304 can be a utility grid source and a backup power source. For example, the backup power source can include any of a plurality of different power sources including, but not limited to, generators, batteries, solar power systems, wind power systems, thermal energy systems, other types of regenerative power sources, or any combination thereof. The system 300 can be an electrical system for powering one or more devices from at least one power source. In some embodiments, the system 300 can include a control circuit 360.

The system 300 can include a control circuit 360. The control circuit 360 can be electrically connected to the switch block 302 to selectively operate the SSSDs in the hybrid switch device 202a and hybrid switch device 202b to provide the high efficiency nominal conduction capability and the higher current-time conduction capability during an overload or fault event. In some embodiments, each of the hybrid switch device 202a and hybrid switch device 202b can include a control circuit configured to control the switching operation of the respective hybrid switch device 202a and hybrid switch device 202b, and the control circuits of the hybrid switch device 202a and hybrid switch device 202b can be in electronic communicable connection with each other to coordinate their switching operations to perform the operations described herein in the present disclosure. For example, the control circuits of hybrid switch device 202a and hybrid switch device 202b can be in electronic communicable connection with each other directly or through a wireless connection. For example, the control circuit 360 can be in electronic communication with the control circuits of each of the hybrid switch device 202a and hybrid switch device 202b directly or through a wireless connection.

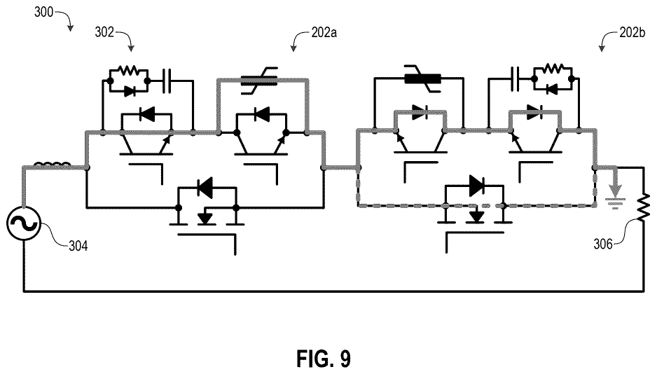

FIG. 9 is a schematic diagram of the example system 300 providing higher current-time conduction capabilities, according to some embodiments.

System 300 includes switch block 302 located between power source 304 and load 306. The switch block 302 includes hybrid switch device 202a connected in anti-series to hybrid switch device 202b such that the switch block 302 has a bipolar configuration. Accordingly, the switch block 302 is a four-quadrant switch capable of conducting current in both directions and blocking voltage in both polarities by selectively operating the SSSDs at hybrid switch device 202a and hybrid switch device 202b.

The switch block 302 exhibits enhanced current time capability and switch voltage utilization ratio during the entire overload event compared to other switch devices. Referring to FIG. 9, shown is an overload or fault event occurring at a positive half cycle of system 300. At switch block 302, the interrupted current flows through the Si Schottky diodes that are co-packed with the IGBTs at SSSD 214 and SSSD 220. The switch block 302 exhibits a lower voltage drop at the SSSD 214 and SSSD 220 in the third quadrant than compared to the body diode in the SiC MOSFETS utilized in the third quadrant by other switch devices.

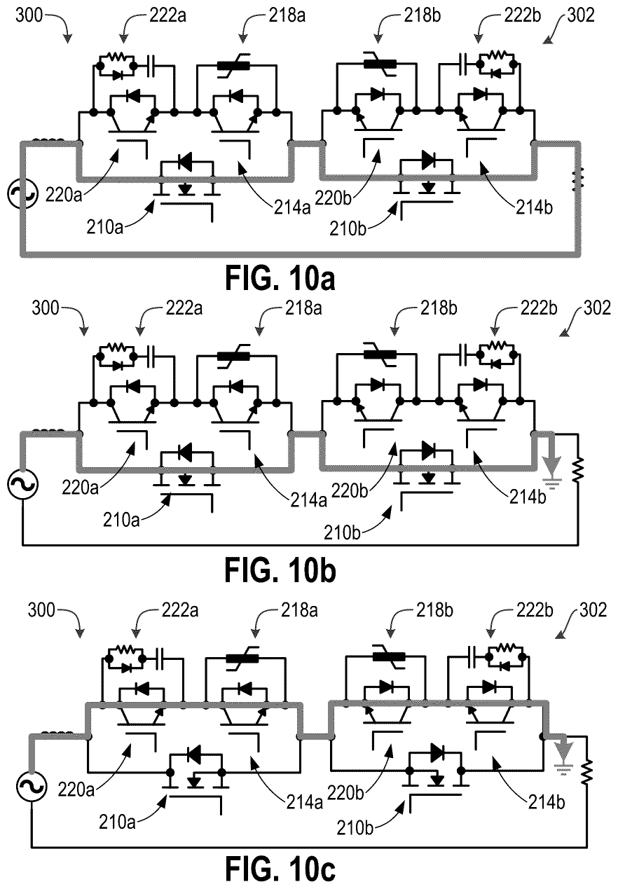

FIGS. 10a-10f are schematic diagrams of the example system 300 providing the higher current-time conduction capabilities, according to some embodiments.

According to some embodiments, the switch block 302 can be utilized in an AC system, and the switch block 302 can include hybrid switch device 202a and hybrid switch device 202b connected in anti-series in a bi-directional configuration. The switch block 302 can be selectively operated by a control circuit such as, for example, control circuit 360 in FIG. 7. The switch block 302 can be selectively operated according to one or more modes, a non-limiting example of which is further described below with reference to FIGS. 10a-10f.

Referring to FIG. 10a, the switch block 302 can be operated in Mode I at (t₀<t≤t₁): During normal operation, SSSD 210a and SSSD 210b supplies nominal current to the load 306. The total switching block 302 nominal efficiency is high due to low conduction losses of SSSD 210a and SSSD 210b at low magnitude nominal current.

Referring to FIG. 10b, the switch block 302 can be operated in Mode II at (t₁<t≤t₂): An overload or fault event occurs in this mode. A surge AC current flows through the SiC MOSFET of SSSD 210a and SSSD 210b. When this current RMS value exceeds the pre-determined current-time profile limit of the SiC MOSFET of SSSD 210a and SSSD 210b, the auxiliary IGBTs of SSSD 214a, SSSD 214b, SSSD 220a, and SSSD 220b turn on shortly before SSSD 210a and SSSD 210b turn off at t=t₂.

Referring to FIG. 10c, the switch block 302 can be operated in Mode III at (t₂<t≤t₃): After SSSD 210a and SSSD 210b turn off, the overload or fault current is commutated from SSSD 210a and SSSD 210b to the IGBTs of SSSD 214a, SSSD 214b, SSSD 220a, and SSSD 220b. At t=t₃, the IGBTs at SSSD 214a, SSSD 214b, SSSD 220a, and SSSD 220b reach the current-time limit and turn off accordingly. The surge AC current withstanding time is extended from t=t₂ to t=t₃ by adding the Si IGBTs, which enhances total switching block current-time capability.

Referring to FIG. 10d, the switch block 302 can be operated in Mode IV at (t₃<t≤t₄): The bottom IGBTs of SSSD 214a and SSSD 220b are responsible for cutting off the current at switching events in positive and negative half cycle. Taking positive half cycle as an example, SSSD 214a turns off at t=t₃ when the surge current is commutated from SSSD 214a to the MOV of circuit protection device 218a. SSSD 214a and total switching block 302 voltage is clamped to V_{op_max}, until current is interrupted and stabilized to MOV leakage current at t=t₄.

Referring to FIG. 10e, the switch block 302 can be operated in Mode V at (t 4<t≤t 5): the MOVs such as, for example, of circuit protection device 218a have a relatively stable leakage current in this mode. The duration from t=t₄ to t=t₅ should be limited so that the MOV is not exposed to excessive current which might lead to thermal runaway. IGBTs at SSSD 214a at circuit protection device 218a or SSSD 220b at circuit protection device 218b can be turned off so that the respective MOV is not exposed to excessive current.

Referring to FIG. 10f, the switch block 302 can be operated in Mode VI at (t 5<t): After a relatively stable leakage current is detected at t=t₅, IGBTs at SSSD 220a at circuit protection device 218a and SSSD 214b at circuit protection device 218b are responsible to cut off this low current up to a few amperes in positive and negative half cycle. This leakage current is because the system voltage is elevated to enhance the total switch voltage utilization ratio to reduce overdesign. Taking positive half cycle as an example, due to the switching of SSSD 220a, Vₛₐ₁ of SSSD 220a increases because of charging of snubber circuit while V_{Sa2} of SSSD 214a decreases. The MOV leakage current is cut off after t=t₅. As the MOV current at this stage is lower than the IGBT leakage current (tens of microamperes), in each positive half cycle V_{Sa2} RMS value of SSSD 214a stabilizes at the MOV AC nominal voltage rating V_{M(AC)} while V_{Sa1} RMS of SSSD 220a stabilizes at V_{AC}-V_{M(AC)}. Similarly, in each negative half cycle, V_{Sa3} of SSSD 214b and V_{Sa4} of SSSD 220b would experience the same voltage distribution. The switch voltage utilization ratio is thereby established with the enhanced V_{AC} while maintaining safe operation without significant leakage current.

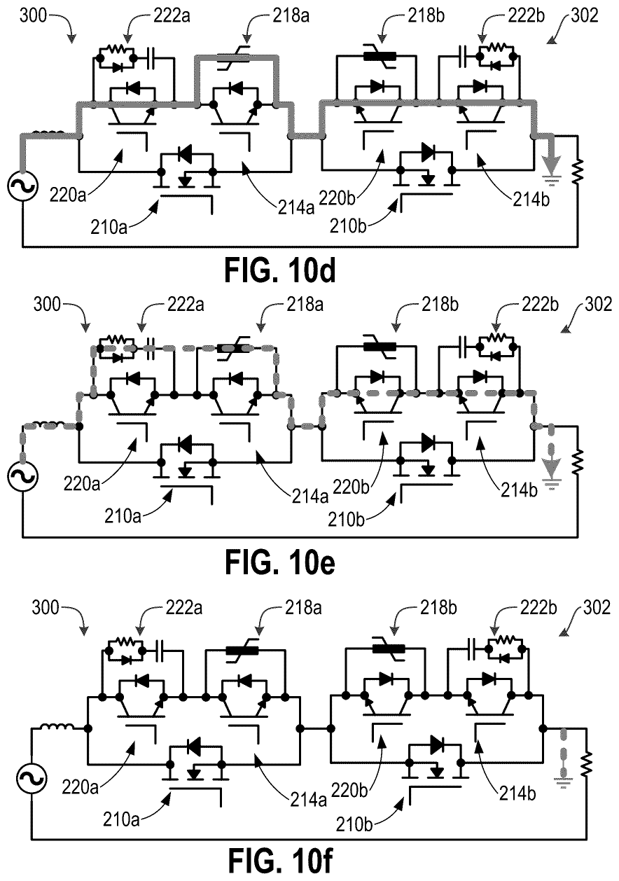

FIG. 11 is a flow diagram of an example method 400, according to some embodiments. The method 400, or one or more portions thereof, can be performed by the hybrid switch device 102, 202 or the switch block 302.

At 402, the method 400 can include detecting a surge current indicative of a fault condition at a circuit configured to couple a power source to a load. The circuit can be, for example, a circuit of system 100 as described with regards to FIG. 1, a circuit of system 200 as described with regards to FIG. 3, or a circuit of system 300 as described with regards to FIG. 7. The power source can be, for example, the power source 104 as described with regards to FIG. 1, the power source 204 as described with regards to FIG. 3, or the power source 304 as described with regards to FIG. 7. The load can be, for example, the load 106 as described with regards to FIG. 1, the load 206 as described with regards to FIG. 3, or the load 306 as described with regards to FIG. 7. The operation 402 can be an embodiment of mode II as described with regards to FIG. 10b.

At 404, the method 400 can include selectively controlling, in response to detecting the surge current, a first switch on a first branch of the circuit and a second switch on a second branch of the circuit to cause current to begin flowing through the second branch and stop flowing through the first branch. In some embodiments, the first switch and the second switch can be selectively controlled to cause the current to flow through the second branch from the first branch in response to approaching a current-time limit profile of the first switch. The first switch on the first branch can be, for example, SSSD 110 on branch 112 as described with regards to FIG. 1, or SSSD 210 on branch 212 as described with regards to FIG. 3. The second switch on the second branch can be, for example, SSSD 114 on branch 116 as described with regards to FIG. 1, SSSD 214 on branch 216 as described with regards to FIG. 3. The operation 404 can be an embodiment of Modes II, III, IV, V, VI as described with regards to FIGS. 10b-10f.

In some embodiments, prior to the overcurrent or fault event, the method 400 can include conducting a nominal current through the first branch using the first switch. In some embodiments, the method 400 can include sending a gate drive signal to the first switch to turn on the first switch to the closed position and sending a gate drive signal to the second switch to turn off the second switch to the open position to cause the nominal current to flow through the first branch. Conducting the nominal current can be an embodiment of Mode I as described with regards to FIG. 10a.

In some embodiments, during the overload or fault event, the method 400 can include conducting the current through the first branch using the first switch according to a current-time limit profile of the first switch. In some embodiments, during the overload or fault event, the method 400 can include sending a gate drive signal to the first switch to maintain the first switch in the closed position according to the current-time limit profile of the first switch using a control circuit or using a gate driver unit of the control circuit. The control circuit can be, for example, control circuit 160 as described with regards to FIG. 1, control circuit 260 as described with regards to FIG. 3, or control circuit 360 as described with regards to FIG. 3.

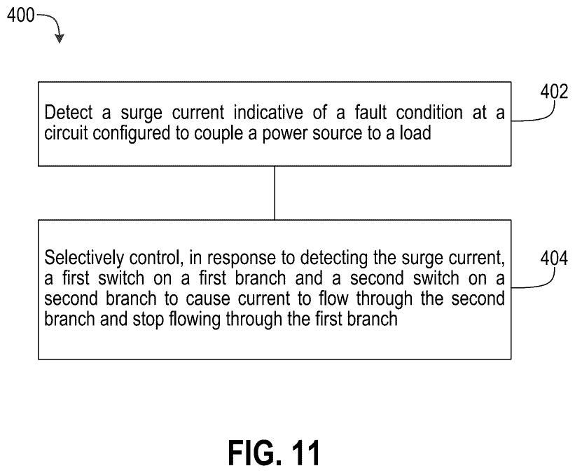

FIG. 12 is a flow diagram of an example method 500, according to some embodiments. The method 500, or one or more portions thereof, can be performed by the hybrid switch device 102, 202 or the switch block 302. The method 500, or one or more portions thereof, can be an embodiment of operation 402 of method 400.

At 502, the method 500 can include conducting the current on the first branch using the first switch according to a current-time limit profile of the first switch. The operation 502 can be an embodiment of Modes I, II as described with regards to FIGS. 10a-10b.

At 504, the method 500 can include driving, in response to exceeding the current-time limit profile of the first switch, the second switch closed and the first switch open such that the current flows from the first branch to the second branch. The operation 504 can be an embodiment of Modes II, III as described with regards to FIGS. 10b-10c.

At 506, the method 500 can include driving, in response to exceeding a current-time limit profile of the second switch, the second switch open. The operation 506 can be an embodiment of Mode IV as described with regards to FIG. 10d. In some embodiments, a first circuit protection device is configured to commutate a voltage at the second switch so as to clamp the voltage at the second branch below a threshold limit. The first circuit protection device is configured to provide overvoltage protection to the second switch. The first circuit protection device can be, for example, circuit protection device 118 as described with regards to FIG. 1 or circuit protection device 218 as described with regards to FIG. 3. The operation of the first circuit protection device can be an embodiment of Mode IV as described with regards to FIG. 10d.

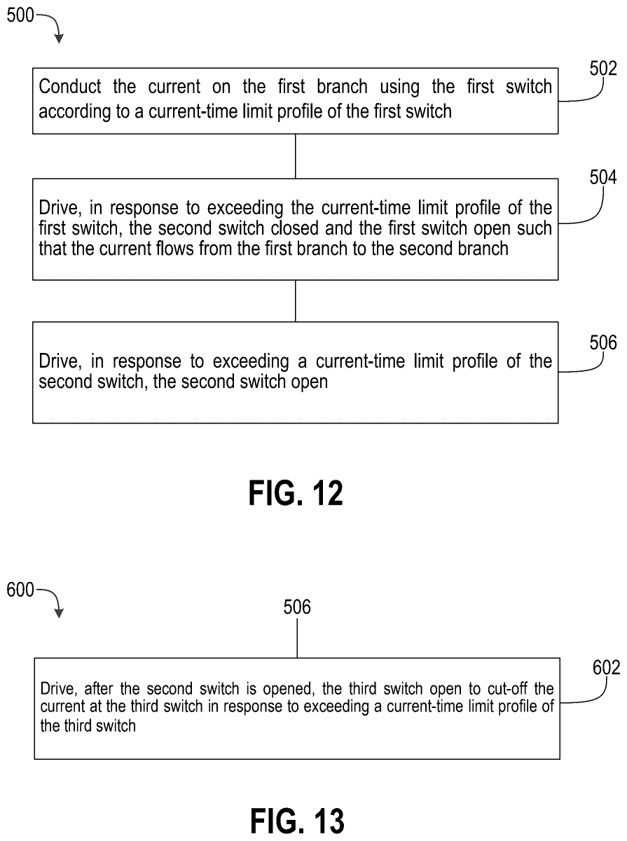

FIG. 13 is a flow diagram of an example method 600, according to some embodiments. The method 600, or one or more portions thereof, can be performed by the hybrid switch device 102, 202 or the switch block 302. The method 600, or one or more portions thereof, can be an embodiment of operation 402 of method 400 or operation 502, 504 of method 500.

At 602, the method 600 can include driving, after the second switch is opened, the third switch can be opened to cut-off the current at the third switch in response to exceeding a current-time limit profile of the third switch. The third switch can be, for example, SSSD 220 as described with regards to FIG. 3. The operation 602 can be an embodiment of Mode VI described with regards to FIG. 10f. In some embodiments, the second circuit protection device is configured to store a voltage commutated from the third switch to decrease the voltage at the first circuit protection device and to clamp the voltage at the second branch below the threshold limit. The second circuit protection device can be, for example, circuit protection device 222 as described above with regards to FIG. 3. The operation of the second circuit protection device can be an embodiment of Mode VI as described above with regards to FIG. 10f.

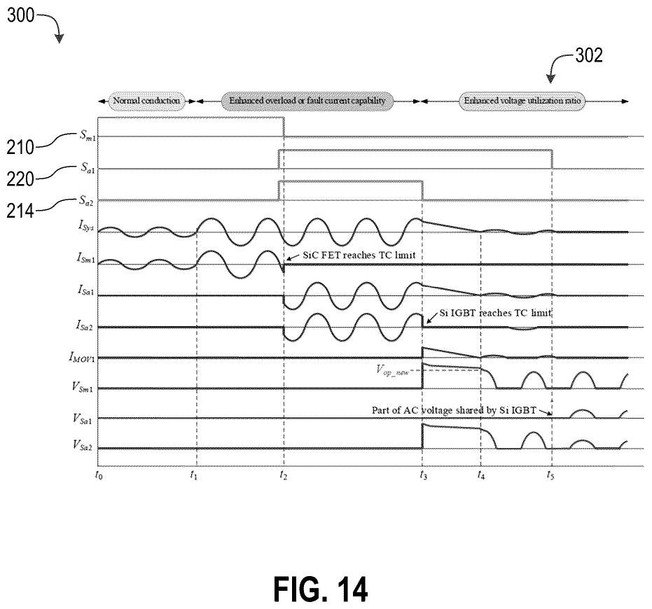

FIG. 14 is a graphical illustration of the switching operation of the hybrid switch device 202 in system 200 of FIG. 3 during an overload or a fault event, according to some embodiments. It is to be appreciated that the operation of the hybrid switch device 202 as illustrated in FIG. 14 can be an embodiment of the one or more modes of operation as described with regards to FIGS. 10a-10f.

The advantages provided by having a topology such as hybrid switch device 202 is shown, such that the hybrid switch device 202 can provide enhanced current-time capability and switch voltage utilization for an entire overload event. The switch block 302 includes a SSSD 210, SSSD 214, and a SSSD 220. The SSSD 210 is located at a first branch for high efficiency nominal conduction. The SSSD 214 and SSSD 220 are provided at a second branch in parallel to the first branch for extending the current-time conduction capability of the hybrid switch device 202. The hybrid switch device 202 can further include a circuit protection device 218 and a circuit protection device 222. The circuit protection device 218 is connected in parallel to SSSD 214 to provide overvoltage protection to SSSD 214 and to clamp a voltage at SSSD 214 to a certain threshold limit, among other benefits. The circuit protection device 222 is connected in parallel to SSSD 220 to provide overvoltage protection to SSSD 220 and to clamp a voltage at SSSD 220 to a certain threshold limit, among other benefits.

The sequence of operation of the one or more components of the hybrid switch device 202, including SSSD 210, SSSD 214, and SSSD 220, during the fault event is shown with regards to t₀-t₅, and beyond. Accordingly, the operation of the hybrid switch device 202 during the fault event can be according to the one or more modes I-VI as described with regards to FIGS. 10a-10f.

All prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “between” does not necessarily require being disposed directly next to other elements. Generally, this term means a configuration where something is sandwiched by two or more other things. At the same time, the term “between” can describe something that is directly next to two opposing things. Accordingly, in any one or more of the embodiments disclosed herein, a particular structural component being disposed between two other structural elements can be: disposed directly between both of the two other structural elements such that the particular structural component is in direct contact with both of the two other structural elements; disposed directly next to only one of the two other structural elements such that the particular structural component is in direct contact with only one of the two other structural elements; disposed indirectly next to only one of the two other structural elements such that the particular structural component is not in direct contact with only one of the two other structural elements, and there is another element which juxtaposes the particular structural component and the one of the two other structural elements; disposed indirectly between both of the two other structural elements such that the particular structural component is not in direct contact with both of the two other structural elements, and other features can be disposed therebetween; or any combination(s) thereof.

As used herein “embedded” means that a first material is distributed throughout a second material.

### ASPECTS

Various Aspects are described below. It is to be understood that any one or more of the features recited in the following Aspect(s) can be combined with any one or more other Aspect(s).

Aspect 1. A device comprising: a first switch configured to couple a power source to a load on a first branch of a circuit; a second switch configured to couple the power source to the load via a second branch of the circuit that is in parallel with the first branch, wherein the first switch comprises a different type of switch than the second switch; a circuit protection device coupled to the second switch such that the circuit protection device is in parallel with the second switch within the second branch; and a control circuit coupled to the first and second switches and configured to selectively control, in response to detecting a surge current, the first and second switches to cause current to begin flowing through the second branch and stop flowing through the first branch.

Aspect 2. The device according to aspect 1, wherein selectively controlling the first and second switches to cause current to begin flowing through the second branch and stop flowing through the first branch comprises: conduct the current on the first branch using the first switch according to a current-time limit profile of the first switch; drive, in response to exceeding the current-time limit profile of the first switch, the second switch closed and the first switch open such that the current flows from the first branch to the second branch; and drive, in response to exceeding a current-time limit profile of the second switch, the second switch open to cut-off the current at the second switch, wherein the circuit protection device is configured to commutate a voltage so as to clamp the voltage at the second branch below a threshold limit.

Aspect 3. The device according to any of the preceding aspects, wherein the circuit protection device is a voltage clamping circuit comprising at least one of: a metal-oxide-varistor, or a transient-voltage-suppression diode.

Aspect 4. The device according to any of the preceding aspects, wherein the circuit protection device comprises a first circuit protection device, and the device further comprises: a third switch configured to couple the power source to the load via the second branch of the circuit that is in series with the second switch, wherein the third switch comprises a different type of switch than the first switch; and a second circuit protection device coupled to the third switch such that the second circuit protection device is in parallel with the third switch within the second branch, wherein the control circuit is further configured to selectively control the third switch to cause current to being flowing through the second branch and stop flowing through the first branch.

Aspect 5. The device according to aspects 2, 3, or 4, wherein the control circuit is further configured to: drive, after the second switch is opened, the third switch open to cut-off the current at the third switch in response to exceeding a current-time limit profile of the third switch, wherein the second circuit protection device is configured to store a voltage commutated from the third switch to clamp the voltage at the second branch below a threshold limit and to decrease the voltage at the first circuit protection device.

Aspect 6. The device according to aspects 4 or 5, wherein the second circuit protection device is a snubber circuit comprising at least one of: a resistor, a capacitor, a diode, or a varistor.

Aspect 7. The device according to aspects 4, 5, or 6, wherein the second circuit protection device comprises at least one of: a first snubber circuit comprising the resistor and the capacitor, a second snubber circuit comprising the resistor, the capacitor, and the diode, or a third snubber circuit comprising the resistor, the capacitor, and the varistor.

Aspect 8. The device according to aspects 4, 5, 6, or 7, wherein the circuit is a two-quadrant switch.

Aspect 9. The device according to aspects 4, 5, 6, 7, or 8, wherein the first switch comprises a SiC MOSFET, and wherein each of the second switch and the third switch comprises a Si IGBT comprising an IGBT co-packed with a Si Schottky diode.

Aspect 10. The device according to any of the preceding aspects, wherein the circuit comprises a first circuit, and wherein the device further comprises a second circuit configured to couple the power source to the load such that the second circuit is in anti-series connection with the first circuit, wherein the first circuit and the second circuit defines a four-quadrant circuit.

Aspect 11. A system comprising: at least one circuit comprising: a first switch configured to couple a power source to a load on a first branch of the at least one circuit; a second switch configured to couple the power source to the load via a second branch of the at least one circuit that is in parallel with the first branch, wherein the second switch comprises a different type of switch than the first switch, and a circuit protection device coupled to the second switch such that the circuit protection device is in parallel with the second switch within the second branch; and a control circuit coupled to the first and second switches and configured to selectively control, in response to detecting a surge current, the first and second switches to cause current to begin flowing through the second branch and stop flowing through the first branch.

Aspect 12. The system according to aspect 11, wherein the circuit protection device comprises a first circuit protection device, and the at least one circuit further comprises: a third switch configured to couple the power source to the load via the second branch of the at least one circuit that is in series with the second switch, wherein the third switch comprises a different type of switch than the first switch; and a second circuit protection device coupled to the third switch such that the second circuit protection device is in parallel with the third switch within the second branch, wherein the control circuit is further configured to selectively control the third switch to cause current to being flowing through the second branch and stop flowing through the first branch.

Aspect 13. The system according to aspect 12, wherein the control circuit is configured to: conduct the current on the first branch using the first switch according to a current-time limit profile of the first switch; drive, in response to exceeding the current-time limit profile of the first switch, the second switch closed and the first switch open such that the current flows from the first branch to the second branch; drive, in response to exceeding a current-time limit profile of the second switch, the second switch open to cut-off the current at the second switch; and drive, after the second switch is opened, the third switch open to cut-off the current at the third switch in response to exceeding a current-time limit profile of the third switch, wherein the first circuit protection device is configured to commutate a voltage so as to clamp the voltage below a threshold limit during operation of the second switch, wherein the second circuit protection device is configured to store a voltage commutated from the third switch to clamp the voltage at the second branch below the threshold limit and to decrease the voltage at the first circuit protection device.

Aspect 14. The system according to any of the preceding aspects, wherein the first circuit protection device comprises a voltage clamping circuit comprising at least one of: a metal-oxide-varistor, or a transient-voltage-suppression diode.

Aspect 15. The system according to aspects 12, 13, or 14, wherein the second circuit protection device comprises at least one of: a first snubber circuit comprising a resistor and a capacitor; a second snubber circuit comprising the resistor, the capacitor, and a diode; or a third snubber circuit comprising the resistor, the capacitor, and a varistor.

Aspect 16. The system according to any of the preceding aspects, wherein the at least one circuit comprises: a first hybrid switching circuit, and a second hybrid switching circuit in anti-series connection with the first hybrid switching circuit, wherein the first and second hybrid switching circuits are in a bipolar configuration.

Aspect 17. The system according to aspects 12, 13, 14, 15, or 16, wherein the first switch comprises a SiC MOSFET, and wherein each of the second switch and the third switch comprises a Si IGBT comprising an IGBT co-packed with a Si Schottky diode.

Aspect 18. A method comprising: detecting a surge current indicative of a fault condition at a circuit configured to couple a power source to a load; and selectively controlling, in response to detecting the surge current, a first switch on a first branch of the circuit and a second switch on a second branch of the circuit to cause current to begin flowing through the second branch and stop flowing through the first branch.

Aspect 19. The method according to aspect 18, wherein selectively controlling the first switch on the first branch of the circuit and the second switch on the second branch of the circuit comprises: conducting the current on the first branch using the first switch according to a current-time limit profile of the first switch; drive, in response to exceeding the current-time limit profile of the first switch, the second switch closed and the first switch open such that the current flows from the first branch to the second branch; and drive, in response to exceeding a current-time limit profile of the second switch, the second switch open, wherein a first circuit protection device is configured to commutate a voltage at the second switch so as to clamp the voltage at the second branch below a threshold limit.

Aspect 20. The method according to aspects 18 or 19, wherein the second branch further comprises a third switch and a second circuit protection device, and wherein selectively controlling the first switch on the first branch of the circuit and the second switch on the second branch of the circuit further comprises: drive, after the second switch is opened, the third switch open to cut-off the current at the third switch in response to exceeding a current-time limit profile of the third switch, wherein the second circuit protection device is configured to store a voltage commutated from the third switch to decrease the voltage at the first circuit protection device and to clamp the voltage at the second branch below the threshold limit.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A device comprising:
a first switch configured to couple a power source to a load on a first branch of a circuit;
a second switch configured to couple the power source to the load via a second branch of the circuit that is in parallel with the first branch, wherein the first switch comprises a different type of switch than the second switch;
a circuit protection device coupled to the second switch such that the circuit protection device is in parallel with the second switch within the second branch; and
a control circuit coupled to the first and second switches and configured to selectively control, in response to detecting a surge current, the first and second switches to cause current to begin flowing through the second branch and stop flowing through the first branch.

2. The device of claim 1, wherein selectively controlling the first and second switches to cause current to begin flowing through the second branch and stop flowing through the first branch comprises:
conduct the current on the first branch using the first switch according to a current-time limit profile of the first switch;
drive, in response to exceeding the current-time limit profile of the first switch, the second switch closed and the first switch open such that the current flows from the first branch to the second branch; and
drive, in response to exceeding a current-time limit profile of the second switch, the second switch open to cut-off the current at the second switch,
wherein the circuit protection device is configured to commutate a voltage so as to clamp the voltage at the second branch below a threshold limit.

3. The device of claim 2, wherein the circuit protection device is a voltage clamping circuit comprising at least one of:
a metal-oxide-varistor, or
a transient-voltage-suppression diode.

4. The device of claim 2, wherein the circuit protection device comprises a first circuit protection device, and the device further comprises:
a third switch configured to couple the power source to the load via the second branch of the circuit that is in series with the second switch, wherein the third switch comprises a different type of switch than the first switch; and
a second circuit protection device coupled to the third switch such that the second circuit protection device is in parallel with the third switch within the second branch,
wherein the control circuit is further configured to selectively control the third switch to cause current to being flowing through the second branch and stop flowing through the first branch.

5. The device of claim 4, wherein the control circuit is further configured to:
drive, after the second switch is opened, the third switch open to cut-off the current at the third switch in response to exceeding a current-time limit profile of the third switch,
wherein the second circuit protection device is configured to store a voltage commutated from the third switch to clamp the voltage at the second branch below a threshold limit and to decrease the voltage at the first circuit protection device.

6. The device of claim 4, wherein the second circuit protection device is a snubber circuit comprising at least one of:
a resistor,
a capacitor,
a diode, or
a varistor.

7. The device of claim 6, wherein the second circuit protection device comprises at least one of:
a first snubber circuit comprising the resistor and the capacitor,
a second snubber circuit comprising the resistor, the capacitor, and the diode, or
a third snubber circuit comprising the resistor, the capacitor, and the varistor.

8. The device of claim 4, wherein the circuit is a two-quadrant switch.

9. The device of claim 4, wherein the first switch comprises a SiC MOSFET, and wherein each of the second switch and the third switch comprises a Si IGBT comprising an IGBT co-packed with a Si Schottky diode.

10. The device of claim 1, wherein the circuit comprises a first circuit, and wherein the device further comprises a second circuit configured to couple the power source to the load such that the second circuit is in anti-series connection with the first circuit, wherein the first circuit and the second circuit defines a four-quadrant circuit.

11. A system comprising:
at least one circuit comprising:
a first switch configured to couple a power source to a load on a first branch of the at least one circuit;
a second switch configured to couple the power source to the load via a second branch of the at least one circuit that is in parallel with the first branch, wherein the second switch comprises a different type of switch than the first switch, and
a circuit protection device coupled to the second switch such that the circuit protection device is in parallel with the second switch within the second branch; and
a control circuit coupled to the first and second switches and configured to selectively control, in response to detecting a surge current, the first and second switches to cause current to begin flowing through the second branch and stop flowing through the first branch.

12. The system of claim 11, wherein the circuit protection device comprises a first circuit protection device, and the at least one circuit further comprises:
a third switch configured to couple the power source to the load via the second branch of the at least one circuit that is in series with the second switch, wherein the third switch comprises a different type of switch than the first switch; and
a second circuit protection device coupled to the third switch such that the second circuit protection device is in parallel with the third switch within the second branch,
wherein the control circuit is further configured to selectively control the third switch to cause current to being flowing through the second branch and stop flowing through the first branch.

13. The system of claim 12, wherein the control circuit is configured to:
conduct the current on the first branch using the first switch according to a current-time limit profile of the first switch;
drive, in response to exceeding the current-time limit profile of the first switch, the second switch closed and the first switch open such that the current flows from the first branch to the second branch;
drive, in response to exceeding a current-time limit profile of the second switch, the second switch open to cut-off the current at the second switch; and
drive, after the second switch is opened, the third switch open to cut-off the current at the third switch in response to exceeding a current-time limit profile of the third switch,
wherein the first circuit protection device is configured to commutate a voltage so as to clamp the voltage below a threshold limit during operation of the second switch,
wherein the second circuit protection device is configured to store a voltage commutated from the third switch to clamp the voltage at the second branch below the threshold limit and to decrease the voltage at the first circuit protection device.

14. The system of claim 12, wherein the first circuit protection device comprises a voltage clamping circuit comprising at least one of:
a metal-oxide-varistor, or
a transient-voltage-suppression diode.

15. The system of claim 12, wherein the second circuit protection device comprises at least one of:
a first snubber circuit comprising a resistor and a capacitor;
a second snubber circuit comprising the resistor, the capacitor, and a diode; or
a third snubber circuit comprising the resistor, the capacitor, and a varistor.

16. The system of claim 11, wherein the at least one circuit comprises:
a first hybrid switching circuit, and
a second hybrid switching circuit in anti-series connection with the first hybrid switching circuit,
wherein the first and second hybrid switching circuits are in a bipolar configuration.

17. The system of claim 12, wherein the first switch comprises a SiC MOSFET, and wherein each of the second switch and the third switch comprises a Si IGBT comprising an IGBT co-packed with a Si Schottky diode.

18. A method comprising:
detecting a surge current indicative of a fault condition at a circuit configured to couple a power source to a load; and
selectively controlling, in response to detecting the surge current, a first switch on a first branch of the circuit and a second switch on a second branch of the circuit to cause current to begin flowing through the second branch and stop flowing through the first branch.

19. The method of claim 18, wherein selectively controlling the first switch on the first branch of the circuit and the second switch on the second branch of the circuit comprises:
conducting the current on the first branch using the first switch according to a current-time limit profile of the first switch;
drive, in response to exceeding the current-time limit profile of the first switch, the second switch closed and the first switch open such that the current flows from the first branch to the second branch; and
drive, in response to exceeding a current-time limit profile of the second switch, the second switch open,
wherein a first circuit protection device is configured to commutate a voltage at the second switch so as to clamp the voltage at the second branch below a threshold limit.

20. The method of claim 19, wherein the second branch further comprises a third switch and a second circuit protection device, and wherein selectively controlling the first switch on the first branch of the circuit and the second switch on the second branch of the circuit further comprises:
drive, after the second switch is opened, the third switch open to cut-off the current at the third switch in response to exceeding a current-time limit profile of the third switch,
wherein the second circuit protection device is configured to store a voltage commutated from the third switch to decrease the voltage at the first circuit protection device and to clamp the voltage at the second branch below the threshold limit.
